(19) United States
(12) Patent Application Publication
(10) Pub. No.: US 2026/0205070 A1
(43) Pub. Date: Jul. 16, 2026

(54) Polar Amplifier with Dynamic Duty Cycling

(71) Applicant: Apple Inc., Cupertino, CA (US)

(72) Inventors: Siwei Li, San Diego, CA (US); Kefei Wu, San Diego, CA (US); Morteza Nick, San Diego, CA (US)

(21) Appl. No.: 19/016,212

(22) Filed: Jan. 10, 2025

(51) Int. Cl. H03F 3/24; H03F 1/32; H04B 1/04

(52) U.S. Cl. CPC H03F 3/245; H03F 1/3205; H04B 1/04; H03F 2200/451; H04B 2001/045

(57) ABSTRACT

An electronic device may include wireless circuitry with a polar power amplifier. Gate terminals of transistors in a PMOS portion of the amplifier may receive a first local oscillator (LO) signal. Gate terminals of transistors in an NMOS portion of the amplifier may receive a second LO signal. A tunable clock generator may generate the first and second LO signals based on a binary control signal received from a physical layer (PHY) controller. The PHY controller may supply the binary control signal to weighting/enable transistors in inverter banks of the tunable clock generator to dynamically adjust a duty cycle ratio between the first and second LO signals over time. The PHY controller may perform this adjustment based the characteristics of the radio-frequency signal in a manner that optimizes linearity and power consumption by the amplifier over time, even as the characteristics change.

### FIELD

This disclosure relates generally to electronic devices, including electronic devices with wireless circuitry.

### BACKGROUND

Electronic devices can be provided with wireless communications capabilities. An electronic device with wireless communications capabilities has wireless circuitry with one or more antennas. Wireless transceiver circuitry in the wireless circuitry uses the antennas to transmit and receive radio-frequency signals.

Radio-frequency signals transmitted by an antenna can be fed through one or more power amplifiers, which are configured to amplify low power analog signals to higher power signals more suitable for transmission through the air over long distances. It can be difficult to provide power amplifiers with sufficient levels of performance. For example, if care is not taken, a power amplifier may exhibit insufficient dynamic range and linearity, which can limit the radio-frequency performance of the wireless circuitry.

### SUMMARY

An electronic device may include wireless circuitry. The wireless circuitry may include a transmit path. The transmit path may include a polar power amplifier that outputs a radio- frequency signal. The amplifier may include a p-channel metal-oxide-semiconductor (PMOS) portion and an n-channel metal-oxide-semiconductor (NMOS) portion. The PMOS portion may receive a power supply voltage that carries an amplitude modulation for the radio-frequency signal. Gate terminals of some of the transistors in the PMOS portion of the amplifier may receive a first local oscillator (LO) signal. Gate terminals of some of the transistors in the NMOS portion of the amplifier may receive a second LO signal. The first and second LO signals may carry a phase modulation for the radio-frequency signal.

A tunable clock generator may generate the first and second LO signals based on an oscillating signal and a M-bit binary control signal received from a physical layer (PHY) controller. The tunable clock generator may include, for example, a first bank of M complementary metal-oxide-semiconductor (CMOS) inverters that generate the first LO signal with a first duty cycle and may include a second bank of M CMOS inverters that generate the second LO signal with a second duty cycle. The first and second duty cycles may define a duty cycle ratio between the first and second LO signals.

The PHY controller may have knowledge of one or more characteristics of the radio- frequency signal to be transmitted by the amplifier. The PHY controller may supply a respective bit of the M-bit binary control signal to weighting/enable transistors in each of the M CMOS inverters of the first bank and in each of the M CMOS inverters of the second bank. The M-bit binary control signal may dynamically control the first and second banks to adjust the duty cycle ratio between the first and second LO signals over time. The PHY controller may perform this adjustment based on one or more characteristics of the radio-frequency signal in a manner that optimizes linearity and power consumption by the amplifier over time, even as the characteristic(s) change. For example, the LO signals may be provided as overlapping signals when the radio-frequency signal is at a low power level and/or exhibits high peak to average power ratio (PAPR) and may be provided as non-overlapping signals when the radio-frequency is at a high power level and/or exhibits low PAPR.

An aspect of the disclosure provides wireless circuitry. The wireless circuitry can include a tunable clock generator configured to generate a first local oscillator (LO) signal and a second LO signal, the tunable clock generator being configured to adjust a duty cycle ratio between the first and second LO signals over time. The wireless circuitry can include an amplifier configured to output a radio-frequency signal, wherein the first and second LO signals convey a phase modulation for the radio-frequency signal. The amplifier can include a first power supply input that receives a power supply voltage conveying an amplitude modulation for the radio-frequency signal. The amplifier can include a second power supply input that receives a reference voltage. The amplifier can include a p-type transistor coupled to the first power supply input and having a gate terminal configured to receive the first LO signal. The amplifier can include an n-type transistor coupled to the second power supply input and having a gate terminal configured to receive the second LO signal.

An aspect of the disclosure provides a method of transmitting a radio-frequency signal. The method can include supplying a power supply voltage to a power supply input of an amplifier, wherein the power supply voltage carries an amplitude modulation of the radio- frequency signal. The method can include supplying, using a local oscillator (LO) generator, a first LO signal to a p-channel metal-oxide-semiconductor (PMOS) portion of the amplifier and a second LO signal to an n-channel metal-oxide-semiconductor (NMOS) portion of the amplifier, wherein the first and second LO signals carry a phase modulation of the radio-frequency signal. The method can include controlling, using one or more processors, the LO generator to adjust a duty cycle ratio between the first and second LO signals based on a characteristic of the radio- frequency signal.

An aspect of the disclosure provides wireless circuitry. The wireless circuitry can include a polar amplifier configured to output a radio-frequency signal. The wireless circuitry can include clocking circuitry configured to supply a first local oscillator (LO) signal and a second LO signal to the polar amplifier, wherein the first and second LO signals convey a phase modulation of the radio-frequency signal. The wireless circuitry can include one or more processors configured to control the clocking circuitry to switch, based on one or more characteristics of the radio-frequency signal, between supplying the first and second LO signals to the polar amplifier as overlapping signals and supplying the first and second LO signals to the polar amplifier as non-overlapping signals.

### BRIEF DESCRIPTION OF THE DRAWINGS

FIG. 1 is a diagram of an illustrative electronic device that includes wireless circuitry in accordance with some embodiments.

FIG. 2 is a diagram of illustrative wireless circuitry that includes radio-frequency amplifiers in accordance with some embodiments.

FIG. 3 is a diagram of illustrative transmit circuitry that includes a polar amplifier in accordance with some embodiments.

FIGS. 4 and 5 are circuit diagrams of an illustrative polar amplifier with dynamic duty cycling in accordance with some embodiments.

FIG. 6 is a circuit diagram of an illustrative dynamic duty cycle generator for a polar amplifier in accordance with some embodiments.

FIG. 7 is a state diagram of illustrative operating modes for a polar amplifier with dynamic duty cycling in accordance with some embodiments.

FIG. 8 is a flow chart of illustrative operations involved in transmitting radio-frequency signals using a polar amplifier with dynamic duty cycling.

FIG. 9 is a plot illustrating how dynamically adjusting a duty cycle of clocking signals provided to a polar amplifier may reduce amplitude modulation to phase modulation (AMPM) distortion of the amplifier in accordance with some embodiments.

FIG. 10 is a plot illustrating how dynamically adjusting a duty cycle of clocking signals provided to a polar amplifier may reduce adjacent channel leakage ratio (ACLR) of the polar amplifier in accordance with some embodiments.

### DETAILED DESCRIPTION

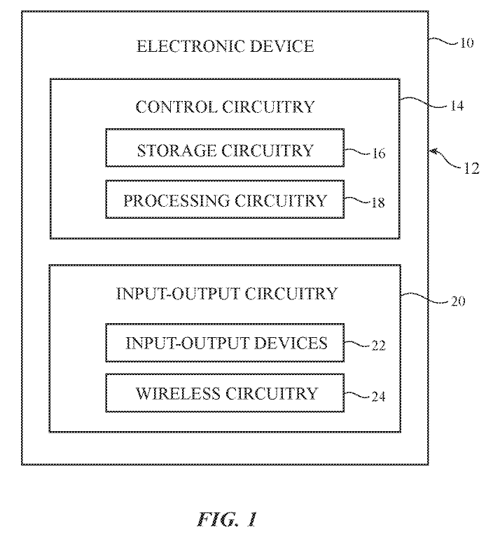

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access- memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols - sometimes referred to as Wi-Fi@), protocols for other short-range wireless communications links such as the Bluetooth® protocol or other wireless personal area network (WPAN) protocols, IEEE 802.11 ad protocols (e.g., ultra- wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), satellite communications (satcom) protocols, antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support or perform radio- frequency signal transmission and/or reception for device 10. Wireless circuitry 24 may be used for wireless communications. Wireless communications performed by wireless circuitry 24 may include or involve wireless data communications (e.g., where wireless data is carried by radio- frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.).

Wireless circuitry 24 may transmit and/or receive radio-frequency signals within a corresponding frequency band at radio frequencies (sometimes referred to herein as a communications band or simply as a "band"). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10- 100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra- wideband (UWB) frequency bands that operate under the IEEE 802.15.4 protocol and/or other ultra-wideband communications protocols, satellite communications (satcom) bands (e.g., an IEEE C band (4-8 GHz), S band (2-4 GHz), L band (1-2 GHz), X band (8-12 GHz), W band (75- 110 GHz), V band (40-75 GHz), K band (18-27 GHz), Kₐ band (26.5-40 GHz), Ku band (12-18 GHz), etc.), unlicensed bands, communications bands under the family of 3GPP wireless communications standards, communications bands under the IEEE 802.XX family of standards, and/or any other desired frequency bands of interest.

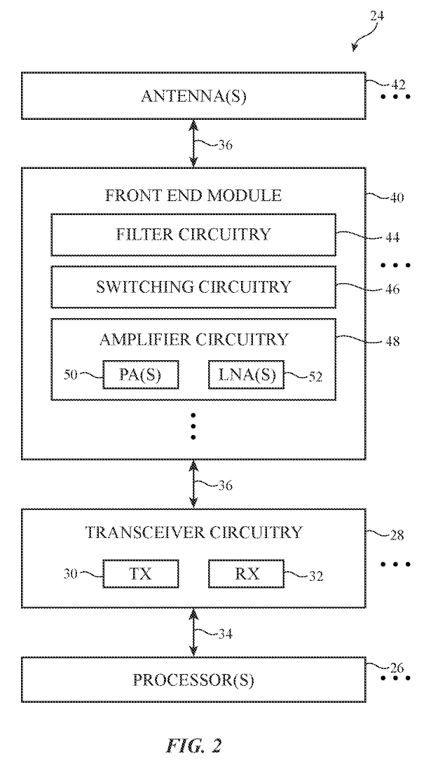

FIG. 2 is a diagram showing illustrative components within wireless circuitry 24. As shown in FIG. 2, wireless circuitry 24 may include a processor such as processor 26, radio- frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio- frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 28, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge- coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio- frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers 50 and/or one or more low-noise amplifier circuits 52), signal attenuators, impedance matching circuitry (e.g., circuitry that helps to match the impedance of antenna 42 to the impedance of radio- frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

As described above, front end module 40 may include one or more power amplifiers (PAs) 50 in the transmit (uplink) path. A power amplifier 50 (sometimes referred to as a radio- frequency power amplifier, transmit amplifier, or amplifier) may be configured to amplify a radio-frequency signal without changing the signal shape, format, or modulation. Amplifier 50 may, for example, be used to provide 10 dB of gain, 20 dB of gain, 10-20 dB of gain, less than 20 dB of gain, more than 20 dB of gain, or other suitable amounts of gain.

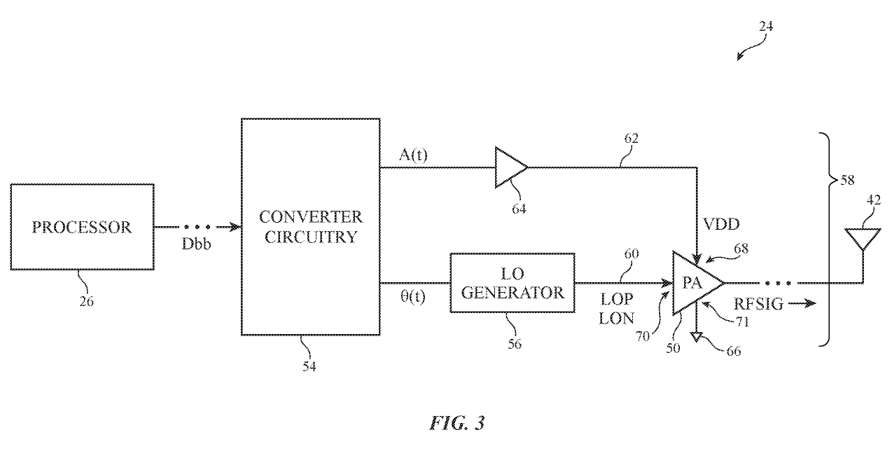

FIG. 3 is a diagram of an illustrative transmit path 58 of wireless circuitry 24. Transmit path 58 is sometimes also referred to herein as transmit chain 58 or transmit circuitry 58. As shown in FIG. 3, wireless circuitry 24 may include processing circuitry such as one or more processors 26, a converter circuitry block such as converter circuitry 54, radio-frequency amplifier circuitry such as radio-frequency amplifier 50 (e.g., a power amplifier), and an antenna 42 configured to radiate radio-frequency signals output by amplifier 50. Additional components (not shown) may also be disposed at different locations along transmit path 58 if desired.

Amplifier 50 may be disposed on FEM 40 or in transceiver circuitry 28 of FIG. 2. Processor(s) 26 may represent one or more processors such as a baseband processor, an application processor, a digital signal processor, a microcontroller, a microprocessor, a central processing unit (CPU), a programmable device, a combination of these circuits, and/or one or more processors within circuitry 18 of FIG. 1. Processor(s) 26 may be configured to generate a digital baseband signal Dbb (e.g., a stream of digital data bits at baseband). Signal Dbb is sometimes referred to as a digital signal or a transmit signal. As examples, the signal Dbb generated by processor(s) 26 may include in-phase (I) and quadrature-phase (Q) signals, radius and phase signals, a vector input, or other digitally coded signals.

In implementations that are described herein as an example, amplifier 50 is implemented as a polar power amplifier (PA). Amplifier 50 is therefore sometimes also referred to herein as polar PA 50, polar radio-frequency amplifier 50, or polar amplifier 50. Polar amplifiers may, for example, be more easily scalable during fabrication/manufacture of wireless circuitry 24 than non-polar amplifier architectures. Implementing amplifier 50 as a polar amplifier may also allow transmit circuitry 58 to be implemented without additional/dedicated mixers for upconverting signals to radio frequencies (e.g., because amplifier 50 is driven using local oscillator signals in a manner that causes the amplifier to output an amplified signal at radio frequencies, as radio-frequency signal RFSIG).

When implemented as a polar amplifier, amplifier 50 may include a first power supply voltage terminal or input such as power supply input 68 (sometimes also referred to herein as power supply terminal 68, power supply input terminal 68, bias terminal 68, or bias input 68). Amplifier 50 may also include a second power supply input such as reference voltage input 71 (sometimes referred to herein as power supply terminal 71, reference terminal 71, reference input 71, bias input 71, bias terminal 71, ground input 71, or ground terminal 71). Reference voltage input 71 may receive a reference potential such as reference voltage 66 (e.g., a ground voltage, VSS, or another reference potential). Reference voltage input 71 and power supply input 68 may, for example, form power supply voltage rails for amplifier 50.

Amplifier 50 may also include a clocking terminal or input that is different from power supply input 68 and reference voltage input 71 such as local oscillator (LO) input 70 (sometimes also referred to herein as LO terminal(s) 70, LO input terminal(s) 70, clocking input 70, or clocking input terminal(s) 70). Amplifier 50 may receive a clocking signal such as a local oscillator signal at its LO input 70. In implementations that are described herein as an example, the clocking signal may include a differential LO signal pair that includes a first (positive) LO signal LOP and a second (negative) LO signal LON. Amplifier 50 may receive a power supply voltage such as power supply voltage VDD at its power supply input 68. Amplifier 50 may generate radio-frequency signal RFSIG using local oscillator signals LOP and LON and using power supply voltage VDD (e.g., without use of upconversion or mixer circuitry that is separate from amplifier 50).

The input of converter circuitry 54 may be communicatively coupled to the output of processor 26. Converter circuitry 54 may have a first output communicatively coupled to the LO input 70 of amplifier 50 over signal path 60. Converter circuitry 54 may also have a second output communicatively coupled to the power supply input 68 of amplifier 50 over signal path 62. Signal path 60 is sometimes also referred to herein as phase signal path 60. Signal path 62 is sometimes also referred to herein as amplitude signal path 62.

Converter circuitry 54 may include signal conversion circuitry such as digital-to-analog converter (DAC) circuitry and cartesian-to-polar converter circuitry. The cartesian-to-polar converter circuitry may be implemented using one or more digital signal processors in converter circuitry 54, as an example. The cartesian-to-polar converter circuitry may convert signal Dbb from a single signal in cartesian coordinates into two different signals in polar coordinates. The two signals in polar coordinates may include an amplitude signal (waveform) A(t) and a corresponding phase signal (waveform) 0(t).

Amplitude signal A(t) represents the amplitude of signal Dbb and the associated radio- frequency signal output by amplifier 50 at times t. Phase signal 0(t) represents the phase of signal Dbb and the associated radio-frequency signal output by amplifier 50 at the same times t. The DAC circuitry in converter circuitry 54 may include, for example, a first DAC (e.g., a first set of one or more DAC cells) that converts amplitude signal A(t) from the digital domain to the analog domain and may include a second DAC (e.g., a second set of one or more DAC cells) that converts phase signal 0(t) from the digital domain to the analog domain. Converter circuitry 54 may output amplitude signal A(t) onto signal path 62 (in the analog domain). Converter circuitry 54 may concurrently output phase signal 0(t) onto signal path 60 (in the analog domain).

If desired, wireless circuitry 24 may include amplifier circuitry such as envelope amplifier 64 disposed on signal path 62 between converter circuitry 54 and amplifier 50. Envelope amplifier 64 may amplify (scale) amplitude signal A(t) to produce the power supply voltage VDD provided to amplifier 50 (e.g., power supply voltage VDD may vary over time according to amplitude signal A(t) or, equivalently, amplitude signal A(t) may represent power supply voltage VDD prior to scaling by envelope amplifier 64). If desired, envelope amplifier 64 may be replaced with any desired power supply voltage generation circuitry (e.g., a power supply integrated circuit, a power management unit, a low-dropout (LDO) regulator, an envelope tracking integrated circuit, etc.) that generates power supply voltage VDD based on amplitude signal A(t) (e.g., by scaling or otherwise processing amplitude signal A(t)). Alternatively, envelope amplifier 64 may be omitted and power supply voltage VDD may be formed from amplitude signal A(t) without scaling or amplification. In general, power supply voltage VDD may be a voltage waveform that encodes or carries the amplitude information (modulation) for/of the radio-frequency signal RFSIG to be output by amplifier 50 (e.g., as represented by amplitude signal A(t)). Power supply input 68 is sometimes also referred to herein as the amplitude modulated or amplitude modulation (AM) input of amplifier 50.

Wireless circuitry 24 may include clocking circuitry such as an LO generator 56 disposed on signal path 60 between converter circuitry 54 and amplifier 50. LO generator 56 may generate the local oscillator signals LOP and LON provided to LO input 70 of amplifier 50 based on phase signal 0(t) (e.g., local oscillator signals LOP and LON may encode phase information (modulations) for the radio-frequency signal RFSIG to be output by amplifier 50). LO generator 56 may include, for example, a synthesizer, signal generator, oscillator circuitry (e.g., a crystal oscillator, a voltage-controlled oscillator (VCO), etc.), loop circuitry (e.g., one or more phase-locked loops, frequency-locked loops, etc.), inverter circuitry, and/or any other desired circuitry that converts phase signal 0(t) into local oscillator signals LOP and LON. More generally, local oscillator signals LOP and LON may be any desired oscillating or periodic clock signals that are used to drive amplifier 50 with the phase modulation output by converter circuitry 54 (e.g., with the phase modulation of the radio-frequency signal RFSIG to be transmitted). The phase modulation (encoding) performed by amplifier 50 under control by local oscillator signals LOP and LON (e.g., based on phase signal 0(t)) and/or the amplitude modulation (encoding) performed by amplifier 50 under control by power supply voltage VDD (e.g., based on amplitude signal A(t)) may collectively represent the wireless data carried by signal Dbb and radio-frequency signal RFSIG (e.g., converter circuitry 54 may convert wireless data in signal Dbb, such as baseband data representing a stream of symbols, packets, frames, datagrams, etc., into a time-varying amplitude modulation carried by amplitude signal A(t) and a time-varying phase modulation carried by phase signal 0(t)).

During signal transmission, local oscillator signals LOP and LON may drive amplifier 50 while amplifier 50 is concurrently powered using the corresponding voltage waveform of power supply voltage VDD. This may cause amplifier 50 to output an amplified radio-frequency signal RFSIG in a corresponding frequency band at its output. Radio-frequency signal RFSIG may have a phase (as a function of time) that is controlled by local oscillator signals LOP and LON and phase signal 0(t). Radio-frequency signal RFSIG may have a corresponding magnitude or amplitude (as a function of time) that is controlled by power supply voltage VDD and amplitude signal A(t). Antenna 42 may radiate radio-frequency signal RFSIG.

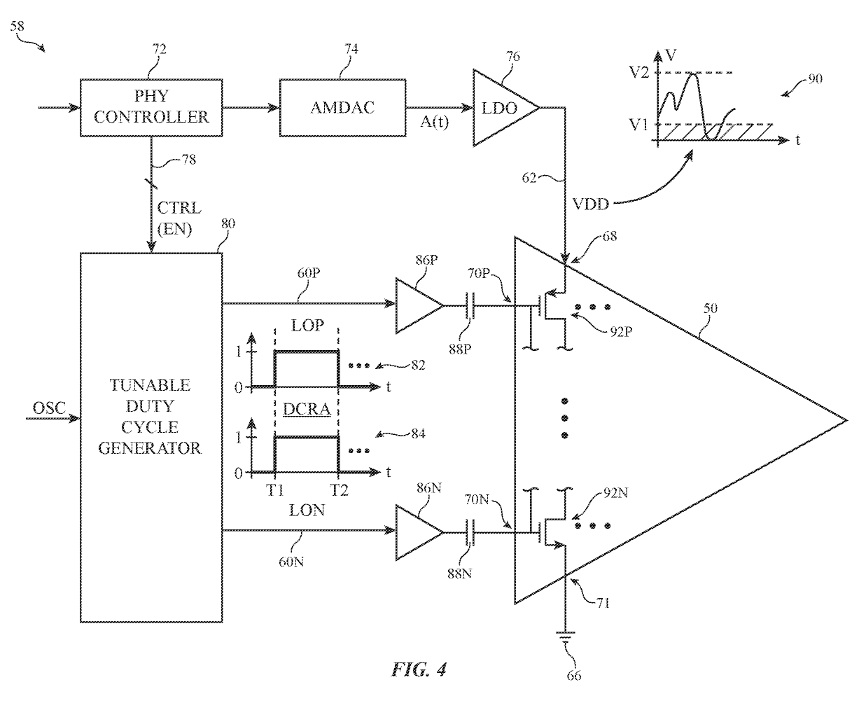

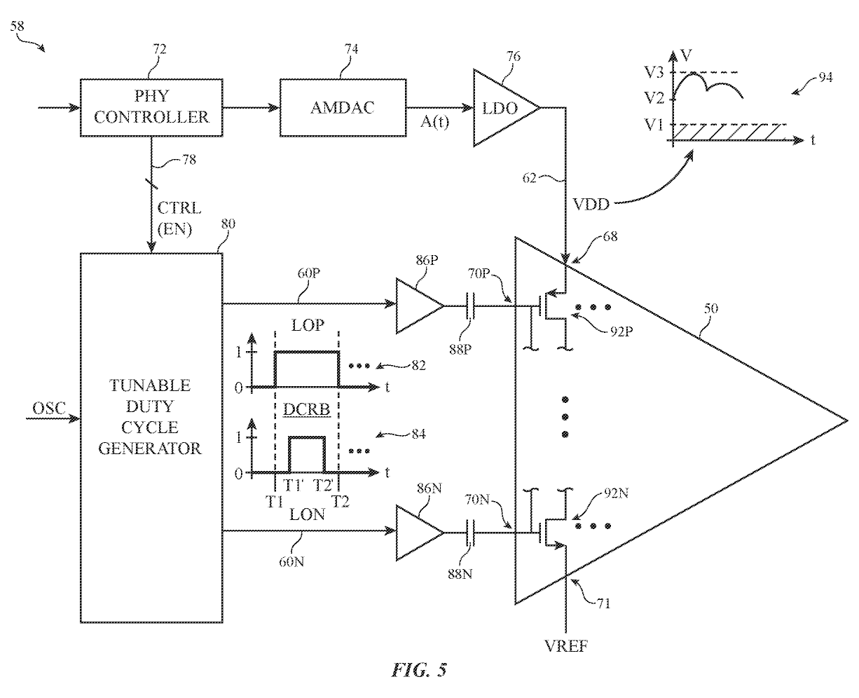

In implementations that are described herein as an example, local oscillator signals LOP and LON may be provided to amplifier 50 with dynamically adjustable duty cycles (e.g., amplifier 50 may generate radio-frequency signal RFSIG using dynamic duty cycling). FIGS. 4 and 5 are circuit diagram showing one example of how local oscillator signals LOP and LON may be provided to amplifier 50 with dynamically adjustable duty cycles.

As shown in FIG. 4, amplifier 50 may be a complementary metal-oxide-semiconductor (CMOS) amplifier having an amplifier core that includes a set of p-channel metal-oxide- semiconductor (PMOS) transistors 92P and a set of n-channel metal-oxide-semiconductor (NMOS) transistors 92N. Transistors 92P are sometimes also referred to herein as PMOS transistors 92P or p-type transistors 92P. Transistors 92N are sometimes also referred to herein as NMOS transistors 92N or n-type transistors 92N.

PMOS transistors 92P may, for example, be used to form one or more PMOS common source stages of amplifier 50 (e.g., PMOS transistors 92P may be PMOS common source transistors). NMOS transistors 92N may, for example, be used to form one or more NMOS common source stages of amplifier 50 (e.g., NMOS transistors 92N may be NMOS common source transistors). The PMOS common source stage and the NMOS common source stage may be coupled in series between the power supply input 68 and the reference voltage input 71 of amplifier 50. Amplifier 50 may also include, for example, one or more cascode stages (e.g., a PMOS cascode stage and an NMOS cascode stage) coupled in series between the PMOS common source stage and the NMOS common source stage (e.g., the PMOS common source stage, a PMOS cascode stage, an NMOS cascode stage, and the NMOS common source stage may be coupled in series between power supply input 68 and reference voltage input 71). Amplifier 50 may have a radio-frequency output coupled between the PMOS and NMOS cascode stages (e.g., between the PMOS and NMOS portions of amplifier 50). The radio-frequency output may be communicatively coupled to antenna 42 (FIG. 3). During signal transmission, amplifier 50 may output radio-frequency signal RFSIG (FIG. 3) at the radio-frequency output.

The signal path 60 coupled to the LO input 70 of amplifier 50 may include a first (e.g., positive) signal line 60P and a second (e.g., negative) signal line 60N. LO input 70 may include a first clocking terminal such as LO input terminal 70P (e.g., for clocking a PMOS portion of amplifier 50 using local oscillator signal LOP) and may include a second clocking terminal such as LO input terminal 70N (e.g., for clocking an NMOS portion of amplifier 50 using local oscillator signal LON). Signal line 60P may be coupled to LO input terminal 70P. Signal line 60N may be coupled to LO input terminal 70N. The gate terminals of transistors 92P may be communicatively coupled to LO input terminal 70P and thus signal line 60P. The gate terminals of transistors 92N may be communicatively coupled to LO input terminal 70N and thus signal line 60N.

The terms "source" and "drain" are sometimes used interchangeably when referring to current-conducting terminals of a metal-oxide-semiconductor (MOS) transistor. The source and drain terminals are therefore sometimes referred to as "source-drain" terminals (e.g., a transistor has a gate terminal, a first source-drain terminal, and a second source-drain terminal). PMOS transistors 92P may each have a respective first source-drain terminal (e.g., source terminals) communicatively coupled to power supply input 68 for receiving power supply voltage VDD. PMOS transistors 92P may each have a respective second source-drain terminal (e.g., drain terminals) communicatively coupled to reference voltage input 71 through NMOS transistors 92N, cascode stages, and/or other circuitry in amplifier 50. NMOS transistors 92N may each have a respective first source-drain terminal (e.g., source terminals) communicatively coupled to reference voltage input 71 for receiving reference voltage 71. NMOS transistors 92N may each have a respective second source-drain terminal (e.g., drain terminals) communicatively coupled to power supply input 68 through PMOS transistors 92P, cascode stages, and/or other circuitry in amplifier 50.

During signal transmission, the gate terminals of PMOS transistors 92P may receive local oscillator signal LOP via LO input terminal 70P. The gate terminals of NMOS transistors 92N may receive local oscillator signal LON via LO input terminal 70N. LO input 70 of amplifier 50 is sometimes also referred to herein as the phase modulated or phase modulation (PM) input of amplifier 50. Local oscillator signal LOP may drive the gate terminals of PMOS transistors 92P to selectively activate or deactivate the transistors (e.g., to cause or stop current flow between the source-drain terminals of the transistors). Local oscillator signal LON may drive the gate terminals of NMOS transistors 92N to selectively activate or deactivate the transistors (e.g., to cause or stop current flow between the source-drain terminals of the transistors). Cascode stages (not shown) in amplifier 50 and the common source stages may drive an output voltage onto the radio-frequency output of amplifier 50.

The term "activate" with respect to a switch (or transistor) may refer to or be defined herein as an action that places the switch in an "on" or low-impedance state such that the two terminals of the switch are electrically connected to conduct current. Activating a switch can sometimes be referred to as turning on or closing a switch. The term "deactivate" with respect to a switch (or transistor) may refer to or be defined herein as an action that places the switch in an "off' or high-impedance state such that the two terminals of the switch/transistor are electrically disconnected with minimal leakage current. Deactivating a switch can sometimes be referred to as turning off or opening a switch. The voltage produced at the radio-frequency output of amplifier 50 may form radio-frequency signal RFSIG (FIG. 3), may exhibit a phase modulation over time as given by local oscillator signals LOP and LON (e.g., based on phase signal 0(t) of FIG. 3), and may exhibit an amplitude modulation over time as given by power supply voltage VDD. The phase and/or amplitude modulations may carry or encode the wireless data of signal Dbb (FIG. 3).

Transmit circuitry 58 may include physical layer (PHY) control circuitry such as PHY controller 72, amplitude modulation (AM) digital-to-analog converter (DAC) circuitry such as AMDAC 74, and an LDO regulator 76 for providing power supply voltage VDD to power supply input 68 of amplifier 50. PHY controller 72 and/or AMDAC 74 may, for example, form a part of converter circuitry 54 (FIG. 3). If desired, PHY controller 72 may form a part of processor 26 (FIG. 3) or other PHY layer processing/control circuitry in device 10. LDO regulator 76 may, for example, form a part of envelope amplifier 64 of FIG. 3. This example is illustrative and non-limiting and, in general, transmit circuitry 58 may include any desired circuitry for providing a power supply voltage VDD that conveys the amplitude modulations for radio-frequency signal RFSIG to amplifier 50.

During signal transmission, PHY controller 72 may receive signal Dbb (FIG. 3), information about signal Dbb, and/or information about the radio-frequency signal RFSIG to be transmitted by amplifier 50. PHY controller 72 may provide a digital amplitude modulation signal to AMDAC 74. AMDAC 74 may convert the digital amplitude modulation signal into amplitude signal A(t). LDO regulator 76 may generate power supply voltage VDD based on amplitude signal A(t).

In some implementations, a static (non-tunable and non-dynamic) clock generator (e.g., in LO generator 56 of FIG. 3) is used to generate the local oscillator signals LOP and LON provided to amplifier 50. The static clock generator includes one or more static chains of inverters, logic NAND gates, logic NOR gates, and/or other non-tunable circuitry. The static clock generator generates local oscillator signal LOP at a first fixed (static) duty cycle and generates local oscillator signal LON at a second fixed (static) duty cycle. Although the second duty cycle may be different than the first duty cycle (e.g., the local oscillator signals may be non- overlapping), the first and second duty cycles remain fixed (constant) over time. This can cause amplifier 50 to be clocked with a non-ideal duty cycle ratio between local oscillator signal LON and local oscillator signal LOP given the current transmission characteristics of radio-frequency signal RFSIG, which can themselves change over time (e.g., as the type or content of data packets to be transmitted change over time). Because the clock generator is non-tunable and local oscillator signals LOP and LON do not have an adjustable duty cycle ratio in this example, the duty cycle ratio cannot be tuned to provide amplifier 50 with improved levels of performance even as characteristics of radio-frequency signal RFSIG change over time. This can, for example, degrade one or more wireless performance metrics (key performance indicators (KPIs) characterizing the performance of amplifier 50 such as error vector magnitude (EVM) and adjacent channel leakage ratio (ACLR).

To mitigate these issues, amplifier 50 may be dynamically clocked using local oscillator signals LOP and LON that are provided with dynamically adjustable duty cycles over time. As shown in FIG. 5, transmit circuitry 58 may include adjustable (tunable) local oscillator signal generation circuitry such as tunable duty cycle generator 80. Tunable duty cycle generator 80 may, for example, form a part of LO generator 56 of FIG. 3. Tunable duty cycle generator 80 may have a first (e.g., positive) output terminal coupled to signal line 60P. Tunable duty cycle generator 80 may have a second (e.g., negative) output terminal coupled to signal line 60N. Tunable duty cycle generator 80 may generate local oscillator signal LOP with a first dynamic duty cycle and may output local oscillator signal LOP onto signal line 60P via its first output terminal. Tunable duty cycle generator 80 may generate local oscillator signal LON with a second dynamic duty cycle and may output local oscillator signal LON onto signal line 60N via its first output terminal. Tunable duty cycle generator 80 may generate local oscillator signals LOP and LON based on a corresponding oscillating signal OSC (e.g., a reference oscillator signal, clock signal, crystal oscillator signal, local oscillator signal, etc.).

PHY controller 72 may provide a digital control signal CTRL (e.g., a multi-bit binary inverter enable signal EN) to tunable duty cycle generator 80 over control path 78. Control signal CTRL may set or configure tunable duty cycle generator 80 to generate local oscillator signal LOP with a particular duty cycle and may control duty cycle generator 80 to change, tune, or adjust the duty cycle of local oscillator signal LOP over time based on one or more characteristics of the radio-frequency signal RFSIG to be transmitted by amplifier 50 (e.g., based on the data packets to be carried by radio-frequency signal RFSIG). Control signal CTRL may also set or configure tunable duty cycle generator 80 to generate local oscillator signal LON with a particular duty cycle and may control duty cycle generator 80 to change, tune, or adjust the duty cycle of local oscillator signal LON over time based on one or more characteristics of the radio-frequency signal RFSIG to be transmitted by amplifier 50 (e.g., based on the data packets to be carried by radio-frequency signal RFSIG).

If desired, transmit circuitry 58 may include a first clock driver 86P (e.g., one or more amplifiers) disposed on signal line 60P between tunable duty cycle generator 80 and amplifier 50. If desired, transmit circuitry 58 may include a capacitance 88P on signal line 60P between clock driver 86P and amplifier 50 (e.g., one or more capacitors and/or distributed capacitances coupled in series and/or parallel between clock driver 86P and LO input terminal 70P). Similarly, if desired, transmit circuitry 58 may include a second clock driver 86N (e.g., one or more amplifiers) disposed on signal line 60N between tunable duty cycle generator 80 and amplifier 50. If desired, transmit circuitry 58 may include a capacitance 88N on signal line 60N between clock driver 86N and amplifier 50 (e.g., one or more capacitors and/or distributed capacitances coupled in series and/or parallel between clock driver 86N and LO input terminal 70N). Clock drivers 86P and 86N may amplify local oscillator signals LOP and LON, respectively, to a desired signal level suitable for driving amplifier 50. Capacitances 88P and 88N may, for example, serve as high pass filters that block a DC component of local oscillator signals LOP and LON, which may help to protect transistors 92P and 92N (e.g., helping to ensure that local oscillator signals LOP and LON always turn the transistors on or off).

FIG. 4 illustrates the operation of amplifier 50 during a first time period in which tunable duty cycle generator 80 provides local oscillator signals LOP and LON to amplifier 50 as overlapping local oscillator signals. Local oscillator signals LOP and LON are referred to and defined herein as "overlapping" local oscillator signals when the duty cycle of local oscillator signal LOP (and equivalently PMOS transistors 92P) is equal to the duty cycle of local oscillator signal LON (and equivalently NMOS transistors 92N), such that local oscillator signals LOP and LON exhibit a duty cycle ratio DCRA that is equal to one (e.g., where the duty cycle ratio (DCR) of local oscillator signals LOP/LON is given by the ratio of the duty cycle of local oscillator signal LOP to the duty cycle of local oscillator signal LON or vice versa). In addition, when generated as overlapping local oscillator signals, the rising edge of each pulse or peak of local oscillator signal LOP (e.g., at time T1 as shown by plot 82 of FIG. 4) is aligned in time with the rising edge of each pulse or peak of local oscillator signal LON (e.g., at time T1 as shown by plot 84 of FIG. 4) and the falling edge of each pulse or peak of local oscillator signal LOP (e.g., at time T2 as shown by plot 82) is aligned in time with the falling edge of each pulse or peak of local oscillator signal LON (e.g., at time T2 as shown by plot 84 of FIG. 4). Put differently, pulses in local oscillator signal LOP may be simultaneous with pulses in local oscillator signal LON when local oscillator signals LOP and LON are output by tunable duty cycle generator 80 as overlapping signals having a duty cycle ratio DCRA equal to one.

Providing local oscillator signals LOP and LON to amplifier 50 as overlapping local oscillator signals may optimize the performance of amplifier 50 for some types of radio- frequency signals RFSIG but may cause amplifier 50 to consume excessive power for other types of radio-frequency signals RFSIG. Consider an example in which the radio-frequency signal RFSIG is to be transmitted at a relatively low output power level while carrying one or more wireless data packets with a relatively high peak-to-average power ratio (PAPR). This may be the case when radio-frequency signal RFSIG is transmitted using certain types of modulation coding schemes such as a 16-QAM modulation, for example. Plot 90 of FIG. 4 illustrates an example voltage waveform of power supply voltage VDD in this type of scenario (e.g., carrying an amplitude modulation for radio-frequency signal RFSIG).

As shown by plot 90, power supply voltage VDD may exhibit a relatively low peak voltage V2 (e.g., 0.8V, 0.6-1.2 V, 0.8-1.2V, 0.8-1 V, etc.) corresponding to the relatively low output power level of radio-frequency signal RFSIG (e.g., amplifier 50 may output radio- frequency signal RFSIG with the relatively low peak output power level when power supply voltage VDD is supplied to amplifier 50 at voltage V2). The high PAPR of the radio-frequency signal may cause some power supply voltage VDD to be provided to amplifier 50 at relatively low voltages such as voltages less than threshold V1 (e.g., 0.2V, 0.5 V, etc.). However, if care is not taken, biasing amplifier 50 at voltages less than threshold V1 may cause amplifier 50 to exhibit reduced linearity (e.g., amplifier 50 may operate in a reduced linearity region when receiving power supply voltage VDD at magnitudes less than threshold V1). Driving the gate terminals of transistors 92P/92N using overlapping local oscillator signals LOP and LON (e.g., with a duty cycle ratio DCRA = 1, as shown by plots 82 and 84) may help to boost the linearity of amplifier 50. As such, PHY controller 72 may control tunable duty cycle generator 80 to transmit local oscillator signals LOP and LON to amplifier 50 as overlapping local oscillator signals when the radio-frequency RFSIG to be transmitted by amplifier 50 exhibits this type of waveform that carries an amplitude modulation given by power supply voltage VDD dropping below threshold V1 (see, e.g., plot 90). This may serve to mitigate the reduction in linearity for amplifier 50 caused by power supply voltage VDD falling below threshold V1. For example, when radio-frequency signal RFSIG is at 8 MHz and is transmitted using a 16-QAM modulation scheme, clocking amplifier 50 using overlapping local oscillator signals LOP/LON may reduce the ACLR of amplifier 50 by as high as 11-12 dB while also improving EVM by as much as 6-7 dB.

On the other hand, clocking amplifier 50 using overlapping local oscillator signals LOP and LON may reduce the efficiency of amplifier 50 when other types of radio-frequency signals RFSIG are to be transmitted. For example, when radio-frequency signal RFSIG is to be transmitted at a relatively high output power level and/or with a relatively low PAPR, driving amplifier 50 using overlapping local oscillator signals LOP and LON may cause amplifier 50 to consume excessive power without risk of falling into the non-linear region. PHY controller 72 may dynamically adjust tunable duty cycle generator 80 (causing tunable duty cycle generator 80 to adjust or tune the duty cycle ratio between local oscillator signals LOP and LON) in a manner that serves to balance the linearity of amplifier 50 with the efficiency of amplifier 50 (e.g., to optimize efficiency and linearity given the particular characteristics of the radio-frequency signal RFSIG that is being transmitted).

FIG. 5 illustrates another example in which PHY controller 72 controls tunable duty cycle generator 80 to generate local oscillator signals LOP and LON as non-overlapping local oscillator signals during a second time period. Local oscillator signals LOP and LON are referred to and defined herein as "non-overlapping" local oscillator signals when duty cycle of local oscillator signal LOP (and equivalently PMOS transistors 92P) is different than the duty cycle of local oscillator signal LON (and equivalently NMOS transistors 92N), such that local oscillator signals LOP and LON exhibit a second duty cycle ratio DCRB that is not equal to one.

When local oscillator signals LOP and LON are non-overlapping local oscillator signals, the width of each pulse of local oscillator signal LON may be different than the width of the corresponding pulse of local oscillator signal LOP and/or the width of each minimum of local oscillator signal LON may be different than the width of the corresponding minimum of local oscillator signal LOP. In addition, the rising edge of each pulse of local oscillator signal LON may be at a different than time than the rising edge of each pulse in local oscillator signal LOP and/or the falling edge of each pulse of local oscillator signal LON may be at a different than time than the falling edge of each pulse in local oscillator signal LOP. For example, as shown by plot 98, the rising edge of local oscillator signal LON may be at time T1 after time T and prior to time T2 and the falling edge of local oscillator signal LON may be at time T2' after time T1' and prior to time T2.

Driving amplifier 50 using non-overlapping local oscillator signals LOP and LON in this way may help to boost the efficiency of amplifier 50 when the waveform of radio-frequency signal RFSIG does not otherwise require amplifier 50 to be biased by a power supply voltage VDD that falls below threshold V1. Consider an example in which the radio-frequency signal RFSIG is to be transmitted at a relatively high output power level while carrying one or more wireless data packets with a relatively low PAPR. Plot 94 of FIG. 5 illustrates an example voltage waveform of power supply voltage VDD in this type of scenario.

As shown by plot 94, power supply voltage VDD may exhibit a relatively high peak voltage V3 > V2 (e.g., 1.6V, 1-2 V, 1.2-1.8V, etc.) corresponding to the relatively high output power level of radio-frequency signal RFSIG (e.g., amplifier 50 may output radio-frequency signal RFSIG with the relatively high peak output power level when power supply voltage VDD is supplied to amplifier 50 at voltage V3). Because the radio-frequency signal exhibits low PAPR in this example, power supply voltage VDD does not drop below threshold V1. As such, the linearity improvement associated with clocking amplifier 50 using overlapping local oscillator signals LOP and LON (as shown in FIG. 4) is not needed, and providing the local oscillator signals as non-overlapping local oscillator signals (as shown in FIG. 5) may cause a reducing in power consumption and an improvement to efficiency of amplifier 50.

In this example, local oscillator signal LOP may be pulsed high for 53% of the period of the oscillating signal OSC received by tunable duty cycle generator 80 (e.g., a reference oscillator signal used to form produce the local oscillator signals) whereas local oscillator signal LON is pulsed high for 47% of the period of local oscillator signal OSC. In this example, duty cycle ratio DCRB may be given by the ratio 53/47, which is not equal to one (e.g., because local oscillator signals LOP and LON are non-overlapping in FIG. 5). This may, for example, help to reduce power consumption by amplifier 50 by as high as 6-7% relative to when amplifier 50 is driven using overlapping local oscillator signals. On the other hand, in the example of FIG. 4, local oscillator signals LOP and LON are each pulsed high for 50% of the period of oscillating signal OSC when output as overlapping local oscillator signals, corresponding to a duty cycle DCRA = 50/50 = 1.

The examples of FIGS. 4 and 5 illustrate just two duty cycle ratios for local oscillator signals LOP and LON, corresponding to two different operating modes of amplifier 50 (e.g., a low power / high PAPR mode in which the local oscillator signals are provided at duty cycle ratio DCRA = 1 and a high power / low PAPR mode in which the local oscillator signals are provided at a first duty cycle DCRB that is not equal to one). This is illustrative and non- limiting. In general, PHY controller 72 may control tunable duty cycle generator 80 to switch between a set of N different duty cycle ratios for local oscillator signals LOP and LON, each corresponding to a different one of N different operating modes of amplifier 50. Each duty cycle ratio and operating mode may correspond to an optimal balance of linearity and efficiency for amplifier 50 under a different respective combination of characteristics of the radio-frequency signal RFSIG transmitted by amplifier 50.

For example, PHY controller 72 may control tunable duty cycle generator 80 to generate local oscillator signals LOP/LON as overlapping local oscillator signals with a first duty cycle ratio DCRA = 1 within a first time period during which the transmitted radio-frequency signal RFSIG is to exhibit a first set of one or more characteristics (e.g., optimizing the balance between linearity and efficiency when radio-frequency signal RFSIG exhibits relatively low power and relatively high PAPR), may control tunable duty cycle generator 80 to generate local oscillator signals LOP/LON as non-overlapping local oscillator signals with a second duty cycle ratio DCRB = 55/45 within a second time period during the transmitted radio-frequency signal RFSIG is to exhibit a second set of one or more characteristics (e.g., optimizing the balance between linearity and efficiency when radio-frequency signal RFSIG exhibits a relatively high power and/or a relatively high PAPR), may control tunable duty cycle generator 80 to generate local oscillator signals LOP/LON as non-overlapping local oscillator signals with a second duty cycle ratio DCRB = 53/47 within a third time period during which the transmitted radio- frequency signal RFSIG is to exhibit a third set of one or more characteristics (e.g., optimizing the balance between linearity and efficiency when radio-frequency signal RFSIG exhibits a first intermediate power and/or a first intermediate PAPR), may control tunable duty cycle generator 80 to generate local oscillator signals LOP/LON as non-overlapping local oscillator signals with a third duty cycle ratio DCRB = 52/48 within a fourth time period during which the transmitted radio-frequency signal RFSIG is to exhibit a fourth set of one or more characteristics (e.g., optimizing the balance between linearity and efficiency when radio-frequency signal RFSIG exhibits a second intermediate power and/or a second intermediate PAPR), etc. The duty cycle ratio between non-overlapping local oscillator signals LOP and LON may be any desired values (e.g., 51/49, 52/48, 53/47, 54/46, 55/45, 56/44, 57/43, 58/42, 59/41, 60/40, 61/39, etc.).

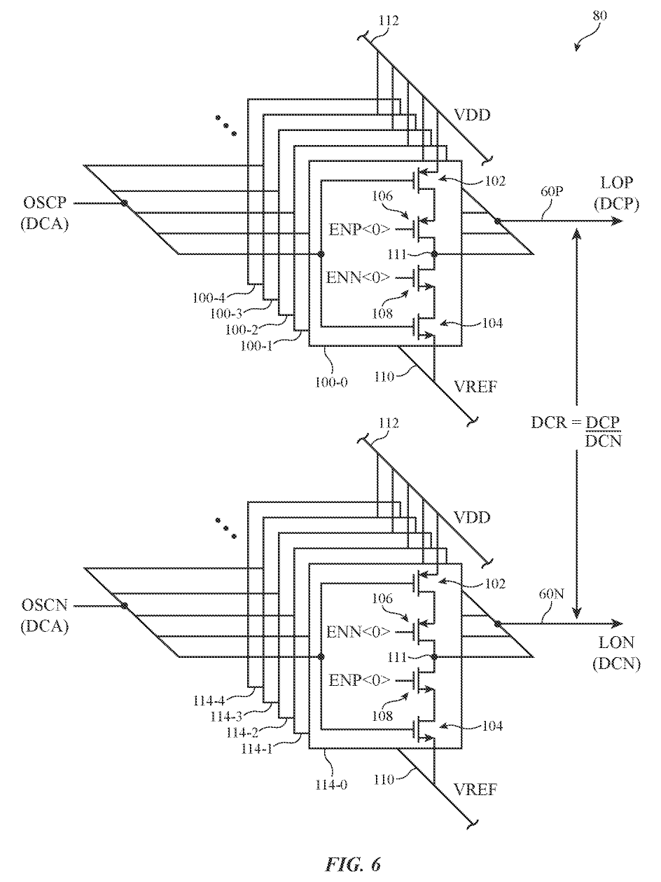

FIG. 6 is a circuit diagram of tunable duty cycle generator 80, showing one example of how tunable duty cycle generator 80 may generate local oscillator signals LOP and LON with a particular duty cycle ratio DCR that is set by PHY controller 72 using control signal CTRL. As shown in FIG. 6, tunable duty cycle generator 80 may include a first bank of M inverters 100 that generate local oscillator signal LOP and may include a second bank of M inverters 114 that generate local oscillator signal LON (e.g., the first and second banks of inverters may each be an M-bit binary controlled tunable local oscillator signal generator). In the example of FIG. 6, M = 5 (e.g., inverters 100-0, 100-1, 100-2, 100-3, and 100-4 may collectively generate local oscillator signal LOP while inverters 114-0, 114-1, 114-2, 114-3, and 114-4 collectively generate local oscillator signal LON). In general, M may be any desired integer.

Each inverter 100 and each inverter 114 may be a CMOS inverter. Each CMOS inverter may include a first PMOS transistor 102, a second PMOS transistor 106, a first NMOS transistor 108, and a second NMOS transistor 104 coupled in series between power supply lines (rails) 112 and 110. Power supply line 112 carries power supply voltage VDD. Power supply line 110 carries reference voltage VREF (e.g., reference voltage 66 of FIG. 4). PMOS transistors 102 and 106 are sometimes also referred to herein as p-type transistors. NMOS transistors 108 and 104 are sometimes also referred to herein as n-type transistors. Transistors 106 and 108 are sometimes also referred to as enable transistors, weighting transistors, or binary weight transistors.

A first source-drain terminal (e.g., the source terminal) of transistor 102 may be coupled to power supply line 112. A second source-drain terminal (e.g., the drain terminal) of transistor 102 may be coupled to a first source-drain terminal (e.g., the source terminal) of transistor 106. A second source-drain terminal (e.g., the drain terminal) of transistor 106 may be coupled to a first source-drain terminal (e.g., the drain terminal) of transistor 108. A second source-drain terminal (e.g., the source terminal) of transistor 108 may be coupled to a first source-drain terminal (e.g., the drain terminal) of transistor 104. A second source-drain terminal (e.g., the source terminal) of transistor 104 may be coupled to power supply line 110. Each inverter 100 may have an output terminal (node) 111 coupled to signal line 60P in parallel. Each inverter 114 may have an output terminal (node) 111 coupled to signal line 60N in parallel. Each output terminal 111 may be coupled to the second source-drain terminal (e.g., the drain terminal) of the transistor 106 and may be coupled to the first source-drain terminal (e.g., the drain terminal) of the transistor 108 in its corresponding inverter 100 or 114.

The gate terminals of the transistors 102 and 104 in each inverter 100 may receive a first oscillating signal OSCP (e.g., at duty cycle DCA). The gate terminals of the transistors 102 and 104 in each inverter 104 may receive a second oscillating OSCN (e.g., at duty cycle DCA). Oscillating signals OSCP/OSCN may, for example, be a differential signal pair that collectively forms oscillating signal OSC of FIG. 5. The control signal CTRL supplied to tunable duty cycle generator 80 by PHY controller 72 (FIG. 3) may include an M-bit enable signal EN, represented as a differential signal pair ENP/ENN (e.g., where enable signal ENN is the inverse of enable signal ENP). A first bit ENP<0> of control signal CTRL may be provided to the gate terminal of the transistor 106 in inverter 100-0 and to the gate terminal of the transistor 108 in inverter 114- 0. A first bit ENN<0> of control signal CTRL may be provided to the gate terminal of the transistor 108 in inverter 100-0 and to the gate terminal of the transistor 106 in inverter 114-0. A second bit ENP<1> of control signal CTRL may be provided to the gate terminal of the transistor 106 in inverter 100-1 and to the gate terminal of the transistor 108 in inverter 114-1. A second bit ENN<1> of control signal CTRL may be provided to the gate terminal of the transistor 108 in inverter 100-1 and to the gate terminal of the transistor 106 in inverter 114-1. Similarly, additional bits of control signal CTRL may be provided to the gate terminals of the transistors 106 and 108 in the other inverters 100 and 114 of tunable duty cycle generator 80. In this way, each of the M bits of control signal CTRL may be provided to the transistors 106 and 108 in respective inverters 100 and 114, which may form binary weight CMOS inverters.

Control signal CTRL (e.g., enable signals ENP/ENN) may control inverters 100 to generate local oscillator signal LOP based on oscillating signal OSCP. The enable signals may serve as binary weights that selectively enable and disable transistors 106 and 108 in different inverters 100 (e.g., according to the corresponding bit of the M-bit control signal CTRL) to collectively tune the rising and falling edges of each pulse of oscillating signal OSCP to produce corresponding pulses of local oscillator signal LOP on signal line 60P with a first duty cycle DCP (e.g., where the rising and falling edges of local oscillator signal LOP represent rising and falling edges of oscillating signal OSC that have been delayed by a particular amount). At the same time, control circuitry CTRL (e.g., enable signals ENP and ENN) may control inverters 114 to generate local oscillator signal LON based on oscillator signal OSCP. The enable signals may serve as binary weights that selectively enable and disable transistors 106 and 108 in different inverters 114 (e.g., according to the corresponding bit of the M-bit control signal CTRL) to collectively tune the rising and falling edges of each pulse of oscillating signal OSCN to produce corresponding pulses of local oscillator signal LON on output on signal line 60P with a second duty cycle DCN. Duty cycles DCP and DCN may be selected to configure local oscillator signals LOP/LON to collectively exhibit a desired duty cycle ratio DCR = DCP/DCN. When the local oscillator signals are output as overlapping local oscillator signals, duty cycle ratio DCR is equal to one (e.g., duty cycle ratio DCRA of FIG. 4). When the local oscillator signals are output as non-overlapping local oscillator signals, duty cycle ratio DCR may be equal to a value other than one (e.g., duty cycle ratio DCRB of FIG. 5).

PHY controller 72 may use control signal CTRL to change, tune, or adjust the binary weighting across the M inverters 100 and the M inverters 114 in tunable duty cycle generator 80 over time to change the duty cycle ratio DCR of local oscillator signals LOP/LON in a manner that produces an optimal balance of linearity and efficiency while driving amplifier 50, depending on the characteristics of the radio-frequency signal RFSIG being output by the amplifier (e.g., by tweaking rise and fall delays of each oscillating signal to tune local oscillator duty cycle separately and precisely for the PMOS and NMOS portions of amplifier 50). PHY controller 72 may, for example, adjust tunable duty cycle generator 80 for every transmit cycle of radio-frequency signal RFSIG in advance (e.g., because PHY controller 72 is aware of the characteristics of every data packet to be carried by radio-frequency signal RFSIG such as transmit power level, modulation type, frequency band, etc.). By increasing the bit depth of control signal CTRL (integer M) and the number of inverters 100 and 114 in tunable duty cycle generator 80, PHY controller 72 may increase the precision/resolution with which duty cycle ratio DCR is set/adjusted (e.g., to finely balance the overall efficiency of amplifier 50 with linearity based on signal power, frequency band, and/or the modulation scheme of radio- frequency signal RFSIG). If desired, duty cycle calibration may be performed to suppress even- harmonics emission. If desired, tunable duty cycle generator 80 may be an auxiliary duty cycle calibration block to extend calibration range.

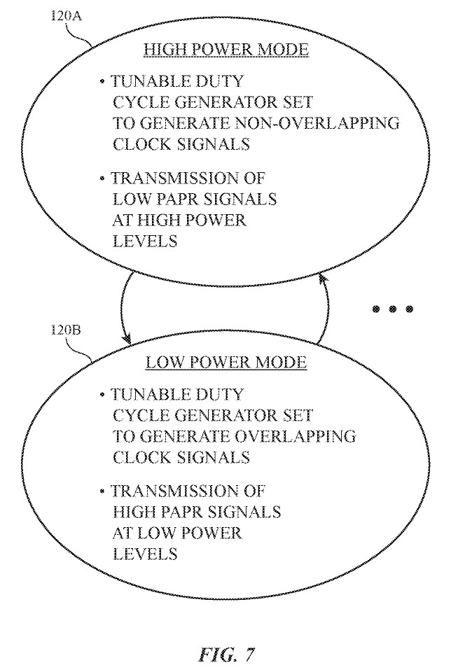

FIG. 7 is a state diagram of illustrative operating modes 120 for amplifier 50 and tunable duty cycle generator 80. As shown in FIG. 7, amplifier 50 and tunable duty cycle generator 80 may be operable in at least a first state (mode) 120A and a second state (mode) 120B. In state 120A (sometimes also referred to herein as high power mode 120A), tunable duty cycle generator 80 may generate local oscillator signals LOP/LON as non-overlapping local oscillator signals (e.g., having duty cycle ratio DCRB of FIG. 5). This may, for example, cause amplifier 50 to transmit radio-frequency signals RFSIG that convey relatively low PAPR data at relatively high output power levels with a sufficient level of efficiency (e.g., without excessive power consumption) and linearity.

In state 120B (sometimes also referred to herein as low power mode 120B), tunable duty cycle generator 80 may generate local oscillator signals LOP/LON as overlapping local oscillator signals (e.g., having duty cycle ratio DCRA of FIG. 4). This may, for example, cause amplifier 50 to transmit radio-frequency signals RFSIG that convey relatively high PAPR data at relatively low output power levels with a sufficient level of linearity and efficiency. This may be generalized to any desired number of modes. Tunable duty cycle generator 80 may clock amplifier 50 using local oscillator signals LOP/LON with a different respective duty cycle ratio DCR in each of the modes (e.g., to optimize linearity and efficiency for any desired number of characteristics of the transmitted signal).

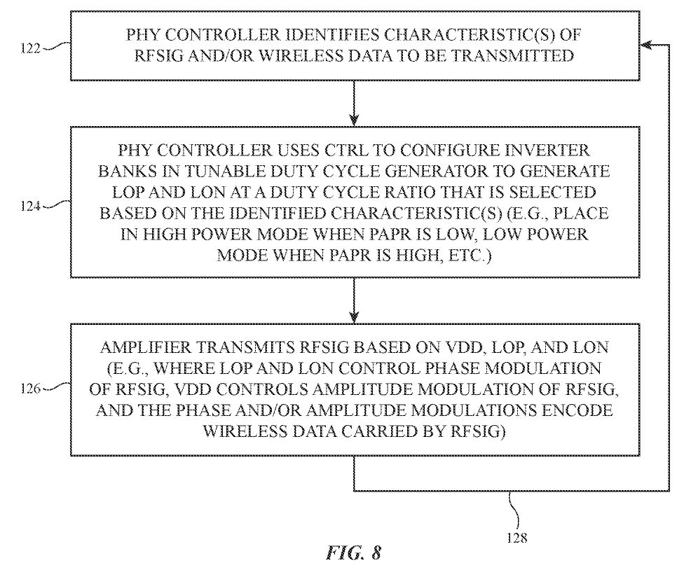

FIG. 8 is a flow chart of illustrative operations that may be performed by transmit circuitry 58 to transmit radio-frequency signals RFSIG. At operation 122, PHY controller 72 may identify one or more characteristics of the radio-frequency signal RFSIG to be transmitted. This may include, for example, a modulation scheme, frequency, bandwidth, transmit power level, a type of carried data, and/or any other desired characteristics of radio-frequency signal RFSIG and/or the wireless data carried by radio-frequency signal RFSIG.

At operation 124, PHY controller 72 may use control signal CTRL to configure the inverters 100 and 114 (FIG. 6) in tunable duty cycle generator 80 to generate local oscillator signals LOP/LON with a duty cycle ratio DCR that is selected based on the identified characteristic(s) of radio-frequency signal RFSIG. The selected duty cycle ratio DCR may be the duty cycle ratio that optimizes efficiency and linearity of amplifier 50 while transmitting radio-frequency signals having the identified characteristic(s). For example, PHY controller 72 may use control signal CTRL to configure tunable duty cycle generator 80 to generate local oscillator signals LOP/LON as overlapping local oscillator signals (e.g., having duty cycle ratio DCRA of FIG. 4), placing amplifier 50 and tunable duty cycle generator 80 in high power mode 120A of FIG. 7, responsive to PHY controller 72 detecting that radio-frequency signal RFSIG is to be transmitted at a relatively low power level and/or with a relatively high PAPR. On the other hand, PHY controller 72 may use control signal CTRL to configure tunable duty cycle generator 80 to generate local oscillator signals LOP/LON as non-overlapping local oscillator signals (e.g., having duty cycle ratio DCRB of FIG. 5), placing amplifier 50 and tunable duty cycle generator 80 in low power mode 120B of FIG. 7, responsive to PHY controller 72 detecting that radio-frequency signal RFSIG is to be transmitted at a relatively high power level and/or with a relatively low PAPR.

At operation 126, amplifier 50 may transmit radio-frequency signals RFSIG having the identified characteristic(s) based on (using) power supply voltage VDD (e.g., carrying amplitude modulations for the radio-frequency signal) and local oscillator signals LOP/LON (e.g., carrying phase modulations for the radio-frequency signal) at the selected duty cycle ratio DCR. Amplifier 50 may transmit the radio-frequency signals with sufficient levels of linearity and efficiency given the identified characteristic(s). Processing may loop back to operation 122 via path 128 as the characteristic(s) of the radio-frequency signals RFSIG change.

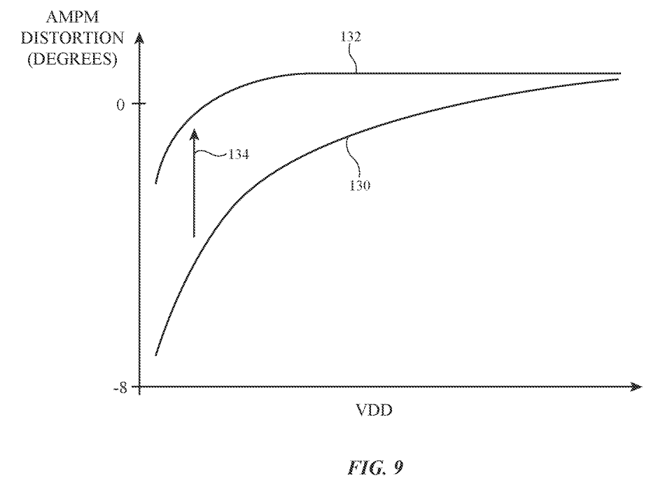

FIG. 9 is a plot of amplitude modulation to phase modulation (AMPM) distortion as a function of power supply voltage VDD for amplifier 50. Curve 134 plots the AMPM distortion when amplifier 50 is provided with non-overlapping local oscillator signals LOP/LON while power supply voltage VDD is relatively low (e.g., less than threshold V1 of FIG. 4). Curve 132 plots AMPM distortion when amplifier 50 is provided with overlapping local oscillator signals LOP/LON while power supply voltage VDD is at the same relatively low level. As shown by curves 130 and 132, clocking amplifier 50 using overlapping local oscillator signals may serve to improve AMPM distortion (e.g., moving the AMPM distortion closer to zero degrees as shown by arrow 134) when power supply voltage VDD is relatively low.

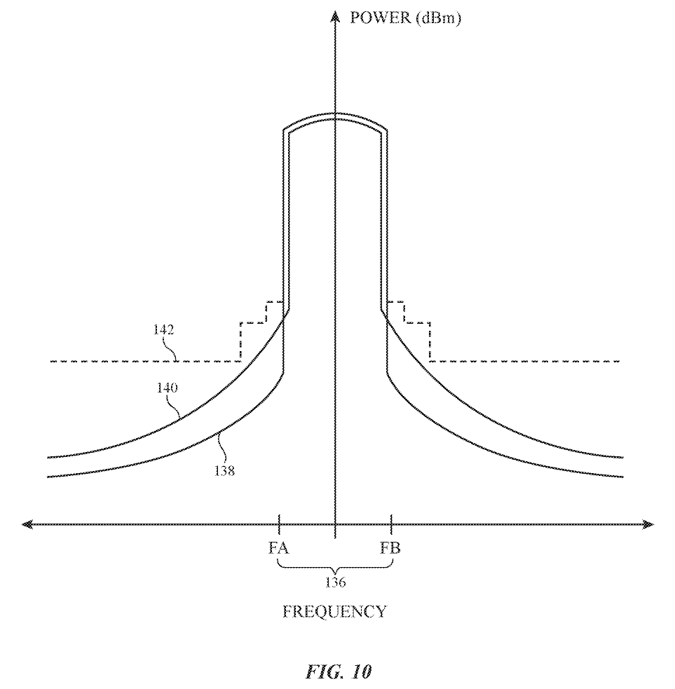

FIG. 10 is a plot showing how dynamic duty cycling of amplifier 50 may improve ACLR for amplifier 50. Curve 140 plots the output power level of radio-frequency signal RFSIG as a function of frequency when amplifier 50 is provided with non-overlapping local oscillator signals LOP/LON while power supply voltage VDD is relatively low (e.g., less than threshold V1 of FIG. 4). As shown by curve 140, RFSIG may be transmitted within a corresponding frequency allocation 136 extending from frequency FA to frequency FB. Frequency allocation 136 may span one or more continuous resource blocks, resource elements, sub-channels, and/or another set of frequency spectrum/resources, and is sometimes also referred to herein as frequency range 136 (e.g., a continuous set of resource blocks/elements, a frequency channel, some or all of frequency/communications band, etc.). Frequency allocation 136 may be determined by a communication schedule for device 10 (e.g., as maintained by a wireless network), by one or more applications running on device 10, by one or more communications requirements imposed on device 10, etc.

As shown by curve 140, radio-frequency signals RFSIG may exhibit a signal peak within frequency allocation 136. However, the low level of power supply voltage VDD places amplifier 50 within its non-linear region below threshold V1. This causes radio-frequency signal RFSIG to exhibit a relatively high signal level at frequencies outside of frequency allocation 136 (e.g., where the signal level gradually drops as an offset from frequency allocation 136 increases). This may cause amplifier 50 to exhibit a relatively high or excessive ACLR. The signal level of radio-frequency signal RFSIG may, for example, approach or exceed a threshold or limit such as emissions mask 142. Emissions mask 142 may represent an upper limit (e.g., as imposed on device 10 by the manufacturer of device 10 or wireless circuitry 24, a regulatory agency or body, a communications protocol or standard governing transmissions by transmit circuitry 58, one or more applications running on device 10, etc.). Exceeding emissions mask 142 outside of frequency allocation 136 may, for example, cause wireless circuitry 24 to fail the emissions mask and/or may otherwise deteriorate the wireless performance of the amplifier, other circuitry in device 10, and/or an external device that receives the radio-frequency signal.

Curve 138 plots the output power level of radio-frequency signal RFSIG as a function of frequency when amplifier 50 is provided with overlapping local oscillator signals LOP/LON while power supply voltage VDD is at the same relatively low level. As shown by curve 138, clocking amplifier 50 using overlapping local oscillator signals LOP/LON may serve to reduce the power level of radio-frequency signal RFSIG outside of frequency allocation 136 (e.g., where the signal level rapidly drops as an offset from frequency allocation 136 increases). This may cause amplifier 50 to exhibit a relatively low ACLR. The examples of FIGS. 9 and 10 are illustrative and non-limiting. In practice, curves 130, 132, 138, and 140 may have other shapes.

The methods and operations described above in connection with FIGS. 1-10 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random- access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

As used herein, the term "concurrent" means at least partially overlapping in time. In other words, first and second events are referred to herein as being "concurrent" with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non- simultaneous (e.g., if the first event starts before or after the start of the second event, if the first event ends before or after the end of the second event, or if the first and second events are partially non-overlapping in time). As used herein, the term "while" is synonymous with "concurrent."

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Wireless circuitry comprising:
a tunable clock generator configured to generate a first local oscillator (LO) signal and a second LO signal, the tunable clock generator being configured to adjust a duty cycle ratio between the first and second LO signals over time; and
an amplifier configured to output a radio-frequency signal, wherein the first and second LO signals convey a phase modulation for the radio-frequency signal and the amplifier includes
a first power supply input that receives a power supply voltage conveying an amplitude modulation for the radio-frequency signal,
a second power supply input that receives a reference voltage,
a p-type transistor coupled to the first power supply input and having a gate terminal configured to receive the first LO signal, and
an n-type transistor coupled to the second power supply input and having a gate terminal configured to receive the second LO signal.

2. The wireless circuitry of claim 1, wherein the tunable clock generator is configured to set the duty cycle ratio between the first and second LO signals based on a characteristic of the radio-frequency signal.

3. The wireless circuitry of claim 2, wherein the characteristic comprises an output power level, a bandwidth, a frequency, a modulation scheme, or a peak to average power ratio.

4. The wireless circuitry of claim 2, further comprising:
a physical layer (PHY) controller configured to control the tunable clock generator to generate the first and second LO signals with a first duty cycle ratio within a first period, the characteristic having a first value during the first period, and configured to control the tunable clock generator to generate the first and second LO signals with a second duty cycle ratio different than the first duty cycle ratio within a second period, the characteristic having a second value different from the first value during the second period.

5. The wireless circuitry of claim 4, wherein the first duty cycle ratio is equal to one and the second duty cycle ratio is not equal to one.

6. The wireless circuitry of claim 5, wherein the characteristic comprises an output power level, the output power level has a first magnitude during the first period, and the output power level has a second magnitude that is greater than the first magnitude during the second period.

7. The wireless circuitry of claim 5, wherein the characteristic comprises a peak to average power ratio (PAPR), the PAPR has a first magnitude during the first period, and the PAPR has a second magnitude that is less than the first magnitude during the second period.

8. The wireless circuitry of claim 1, wherein the amplifier comprises:
a p-type common source stage that includes the p-type transistor; and
an n-type common source stage that includes the n-type transistor.

9. The wireless circuitry of claim 1, further comprising:
a first signal line that couples the tunable clock generator to the gate terminal of the p-type transistor; and
a second signal line that couples the tunable clock generator to the gate terminal of the n-type transistor, wherein the tunable clock generator is configured to generate the first and second LO signals based on an oscillating signal and a binary enable signal.

10. The wireless circuitry of claim 9, further comprising:
a first clock driver disposed on the first signal line;
a first capacitance disposed on the first signal line between the first clock driver and the gate terminal of the p-type transistor;
a second clock driver disposed on the second signal line; and
a second capacitance disposed on the first signal line between the first clock driver and the gate terminal of the n-type transistor.

11. The wireless circuitry of claim 9, wherein the tunable clock generator comprises:
a first bank of complementary metal-oxide-semiconductor (CMOS) inverters having output terminals coupled to the first signal line in parallel; and
a second bank of CMOS inverters having output terminals coupled to the second signal line in parallel, wherein the binary enable signal is configured to control the first bank of CMOS inverters to generate the first LO signal with a first duty cycle, the binary enable signal is configured to control the second bank of CMOS inverters to generate the second LO signal with a second duty cycle, and the first and second duty cycles define the duty cycle ratio between the first and second LO signals.

12. The wireless circuitry of claim 11, wherein the CMOS inverters in the first and second banks of CMOS inverters include:
a first p-channel metal-oxide-semiconductor (PMOS) transistor having a source terminal coupled to a first power supply line and having a gate terminal that receives the oscillating signal;
a second PMOS transistor having a source terminal coupled to a drain terminal of the first PMOS transistor;
a first n-channel metal-oxide-semiconductor (NMOS) transistor having a drain terminal coupled to a drain terminal of the second PMOS transistor; and
a second NMOS transistor having a drain terminal coupled to a source terminal of the first NMOS transistor, a source terminal coupled to a second power supply line, and a gate terminal that receives the oscillating signal, wherein gate terminals of the second PMOS transistor and the first NMOS transistor receive a corresponding bit of the binary enable signal.

13. The wireless circuitry of claim 12, wherein the binary enable signal comprises an M-bit binary enable signal, the first bank of CMOS inverters includes a first set of M CMOS inverters, the second bank of CMOS inverters include a second set of M CMOS inverters, and each bit in the M-bit binary enable signal is provided to the gate terminals of the second PMOS transistor and the first NMOS transistor in a different respective one of the M CMOS inverters of the first set and is provided to the gate terminals of the second PMOS transistor and the first NMOS transistor in a different respective one of the M CMOS inverters of the second set.

14. The wireless circuitry of claim 13, further comprising:
a physical layer (PHY) controller configured to provide the M-bit binary enable signal to the first and second banks of CMOS inverters, wherein the M-bit binary enable signal controls the first and second banks of CMOS inverters to output the first and second LO signals with the duty cycle ratio by shifting rising and falling edges of the oscillating signal.

15. A method of transmitting a radio-frequency signal comprising:
supplying a power supply voltage to a power supply input of an amplifier, wherein the power supply voltage carries an amplitude modulation of the radio-frequency signal;
supplying, using a local oscillator (LO) generator, a first LO signal to a p-channel metal-oxide-semiconductor (PMOS) portion of the amplifier and a second LO signal to an n-channel metal-oxide-semiconductor (NMOS) portion of the amplifier, wherein the first and second LO signals carry a phase modulation of the radio-frequency signal; and
controlling, using one or more processors, the LO generator to adjust a duty cycle ratio between the first and second LO signals based on a characteristic of the radio-frequency signal.

16. The method of claim 15, wherein the characteristic comprises an output power level, a bandwidth, a frequency, a modulation scheme, or a peak to average power ratio.

17. The method of claim 15, wherein controlling the LO generator to adjust the duty cycle ratio comprises:
controlling the LO generator to generate the first and second LO signals using a first duty cycle ratio during a first time period, the first duty cycle ratio being equal to one; and
controlling the LO generator to generate the first and second LO signals using a second duty cycle ratio that is different than the first duty cycle ratio during a second time period that is different from the first time period.

18. The method of claim 15, further comprising:
generating, using a first bank of inverters in the LO generator, the first LO signal based on an oscillating signal; and
generating, using a second bank of inverters in the LO generator, the second LO signal based on the oscillating signal, wherein controlling the LO generator to adjust the duty cycle ratio comprises:
providing a binary enable signal to binary weighting transistors in the first and second banks of inverters, wherein the binary enable signal controls the first bank of inverters to adjust rising and falling edges of the first LO signal and the binary enable signal controls the second bank of inverters to adjust rising and falling edges of the second LO signal.

19. Wireless circuitry comprising:
a polar amplifier configured to output a radio-frequency signal;
clocking circuitry configured to supply a first local oscillator (LO) signal and a second LO signal to the polar amplifier, wherein the first and second LO signals convey a phase modulation of the radio-frequency signal; and
one or more processors configured to control the clocking circuitry to switch, based on one or more characteristics of the radio-frequency signal, between supplying the first and second LO signals to the polar amplifier as overlapping signals and supplying the first and second LO signals to the polar amplifier as non-overlapping signals.

20. The wireless circuitry of claim 19, the one or more processors being further configured to:
control the clocking circuitry to output the first and second LO signals as the overlapping signals while the radio-frequency signal has a first characteristic;
control the clocking circuitry to output the first and second LO signals as the non-overlapping signals with a first duty cycle ratio while the radio-frequency signal has a second characteristic different than the first characteristic; and
control the clocking circuitry to output the first and second LO signals as the non-overlapping signals with a second duty cycle ratio different from the first duty cycle ratio while the radio-frequency signal has a third characteristic different than the first and second characteristics.
